(19) United States
(12) Patent Application Publication
(10) Pub. No.: US 2025/0255015 A1
(43) Pub. Date: Aug. 7, 2025

(54) IMAGE SENSING DEVICE INCLUDING PROTECTION DEVICE

(71) Applicant: SK hynix Inc., Icheon-si (KR)

(72) Inventors: Woo Sung SHIM, Icheon-si (KR); Seung Hoon SA, Icheon-si (KR); Hyuk AN, Icheon-si (KR)

(21) Appl. No.: 19/043,106

(22) Filed: Jan. 31, 2025

(30) Foreign Application Priority Data
Feb. 2, 2024 (KR) 10-2024-0016304

(51) Int. Cl. H10F 39/00; H10F 39/18

(52) U.S. Cl. CPC H10F 39/014; H10F 39/18; H10F 39/8037

(57) ABSTRACT

Image sensing devices including protection devices are discloses. In an embodiment, an image sensing device includes a unit pixel configured to include a protected device, and a protection device electrically connected to the protected device and configured to protect the protected device during a plasma process. The protection device includes an emitter region configured to include impurities of a first conductivity type, a base region configured to surround the emitter region and including impurities of a second conductivity type, a collector region configured to surround the base region and including impurities of the first conductivity type, and an isolation structure disposed between the protection device and another protection device adjacent to the protection device and configured to electrically isolate the base region of the protection device from a base region of the other protection device.

### CROSS-REFERENCE TO RELATED APPLICATION

This patent document claims the priority and benefits of Korean patent application No. 10-2024-0016304, filed on Feb. 2, 2024, the disclosure of which is incorporated herein by reference in its entirety as part of the disclosure of this patent document.

### TECHNICAL FIELD

The technology and implementations disclosed in this patent document generally relate to an image sensing device, and more particularly to an image sensing device including a protection device.

### BACKGROUND

Image sensing devices are commonly used in electronic devices to convert light of optical images into electrical signals. Image sensing devices may be broadly classified into charge coupled device (CCD) image sensing devices and complementary metal oxide semiconductor (CMOS) image sensing devices.

CMOS image sensing devices have the advantage of being operable in a simpler manner than the CCD sensing device, and are compatible with CMOS fabrication technology, making them widely used in recent years.

### SUMMARY

The disclosed technology can be implemented in some embodiments to provide a protection device designed to effectively remove charges stored in a gate of a protected transistor (e.g., a target transistor to be protected) during a plasma process.

The disclosed technology can also be implemented in some embodiments to provide an image sensing device designed to prevent electrical short-circuit between protection devices by providing an isolation structure between adjacent protection devices.

In an embodiment of the disclosed technology, an image sensing device may include a unit pixel configured to include a protected device, and a protection device electrically connected to the protected device and configured to protect the protected device during a plasma process. The protection device may include an emitter region configured to include impurities of a first conductivity type, a base region configured to surround the emitter region and including impurities of a second conductivity type, a collector region configured to surround the base region and including impurities of the first conductivity type, and an isolation structure disposed between the protection device and another protection device adjacent to the protection device and configured to electrically isolate the base region of the protection device from a base region of the other protection device.

In some implementations, the first conductivity type may be P-type, and the second conductivity type may be N-type.

In some implementations, the isolation structure may include a first isolation layer configured to include an insulation material, and a second isolation layer configured to contact a sidewall of the first isolation layer and including impurities of the first conductivity type.

In some implementations, the emitter region may include a first emitter layer configured to include impurities of the first conductivity type, and a second emitter layer disposed below the first emitter layer and configured to include a lower concentration of impurities of the first conductivity type than the first emitter layer.

In some implementations, the base region may include a first base layer configured to include impurities of the second conductivity type, a second base layer disposed below the first base layer and configured to include a lower concentration of impurities of the second conductivity type than the first base layer, a third base layer disposed below the second base layer and configured to include a lower concentration of impurities of the second conductivity type than the second base layer, and a fourth base layer disposed below the third base layer and configured to include a lower concentration of impurities of the second conductivity type than the third base layer.

In some implementations, the collector region may include a first collector layer configured to include impurities of the first conductivity type, and a second collector layer disposed below the first collector layer and configured to include a lower concentration of impurities of the first conductivity type than the first collector layer.

In some implementations, the first emitter layer may include impurities of the first conductivity type at the same concentration as the first collector layer.

In some implementations, the image sensing device may further include a shallow trench isolation (STI) structure disposed between the first emitter layer and the first base layer, and disposed between the first base layer and the first collector layer.

In some implementations, a gate of the protected device may be connected to the emitter region through an interconnect such as a metal line.

In some implementations, the protected device may include at least one of a transfer transistor, a selection transistor, or a reset transistor.

In some implementations, the base region may be in a floating state.

In some implementations, the collector region may be grounded to a ground voltage.

In some implementations, the first isolation layer may be continuously formed between the protection device and the other protection device, and the base region of the protection device may be electrically isolated from the base region of the other protection device.

In some implementations, the first isolation layer may be discontinuously formed between the protection device and the other protection device, and the base region may be electrically connected to the base region of the other protection device to include first isolation layer segments separated from each other.

In another embodiment of the disclosed technology, an image sensing device may include a protected device disposed in a unit pixel region; and a protection device disposed in a protection device region contacting the unit pixel region and connected to the protected device. The protection device may include: an emitter region configured to include P-type impurities; a base region configured to surround the emitter region and including N-type impurities; a collector region configured to surround the base region and including the P-type impurities; and an isolation structure disposed between a base region of the protection device and a base region of another protection device.

In some other implementations, the protected device may include a gate and a gate insulation layer disposed below the gate. The gate may be connected to the emitter region through an interconnect such as a metal line.

In some other implementations, the protected device may include at least one of a transfer transistor, a selection transistor, or a reset transistor.

In some other implementations, the image sensing device may further include: a shallow trench isolation (STI) structure disposed between the emitter region and the base region, and disposed between the base region and the collector region.

In some other implementations, the isolation structure may include: a first isolation layer configured to include an insulation material, and a second isolation layer configured to contact a sidewall of the first isolation layer and including the P-type impurities.

In some other implementations, the second isolation layer may be formed by performing plasma ion implantation.

It is to be understood that both the foregoing general description and the following detailed description of the disclosed technology are illustrative and explanatory and are intended to provide further explanation of the disclosure as claimed.

### BRIEF DESCRIPTION OF THE DRAWINGS

The above and other features and beneficial aspects of the disclosed technology will become readily apparent with reference to the following detailed description when considered in conjunction with the accompanying drawings.

FIG. 1 is a block diagram illustrating an example of an image sensing device based on an embodiment of the disclosed technology.

FIG. 2 is a schematic diagram illustrating an example of a pixel array based on an embodiment of the disclosed technology.

FIG. 3 is a schematic diagram illustrating an example of some parts of a pixel array based on an embodiment of the disclosed technology.

FIG. 4 is a circuit diagram illustrating an example of some parts of an equivalent circuit of an image sensing device based on an embodiment of the disclosed technology.

FIG. 5 is a plan view illustrating an example of a first protection device shown in FIG. 3 based on an embodiment of the disclosed technology.

FIG. 6 is a cross-sectional view illustrating an example of the first protection device taken along a first cutting line shown in FIG. 5 based on an embodiment of the disclosed technology.

FIG. 7 is a plan view illustrating an example of a protection device based on another embodiment of the disclosed technology.

FIG. 8 is a cross-sectional view illustrating an example of the protection device taken along a second cutting line shown in FIG. 7 based on another embodiment of the disclosed technology.

FIG. 9 is a plan view illustrating an example of a protection device based on still another embodiment of the disclosed technology.

FIG. 10 is a plan view illustrating an example of a protection device based on still another embodiment of the disclosed technology.

### DETAILED DESCRIPTION

This patent document provides implementations and examples of an image sensing device including a protection device that may be used to address one or more technical or engineering issues and to mitigate limitations or disadvantages encountered in image sensing devices. Some implementations of the disclosed technology relate to a protection device that can effectively remove charges stored in a gate of a protected transistor (i.e., a target transistor to be protected) during a plasma process. Some implementations of the disclosed technology relate to an image sensing device that can prevent electrical short-circuit between protection devices by providing an isolation structure between adjacent protection devices. To address the issues above, the disclosed technology can be implemented in some embodiments to provide an image sensing device that can effectively protect a protected transistor during a plasma process while preventing electrical short-circuit between adjacent protection devices.

Reference will now be made in detail to the embodiments of the disclosed technology, examples of which are illustrated in the accompanying drawings. Wherever possible, the same reference numbers will be used throughout the drawings to refer to the same or like parts. While the disclosure is susceptible to various modifications and alternative forms, specific embodiments thereof are shown by way of example in the drawings. However, the disclosure should not be construed as being limited to the embodiments set forth herein.

Hereinafter, various embodiments will be described with reference to the accompanying drawings. However, it should be understood that the disclosed technology is not limited to specific embodiments, but includes various modifications, equivalents and/or alternatives of the embodiments. The embodiments of the disclosed technology may provide a variety of effects capable of being directly or indirectly recognized through the disclosed technology.

The terminology used herein is for the purpose of describing particular embodiments only and is not intended to be limiting of the disclosed technology. As used herein, the singular forms are intended to include the plural forms as well, unless the context clearly indicates otherwise. It will be further understood that the terms “comprises”, “includes”, “including”, and/or “comprising,” when used in this specification, specify the presence of stated constituent elements, steps, operations, and/or components, but do not preclude the presence or addition of one or more other constituent elements, steps, operations, and/or components thereof. The term “and/or” may include a combination of a plurality of items or any one of a plurality of items.

Plasma processes play a critical role in the manufacturing of CMOS image sensing devices. These processes are employed in various steps, including dielectric deposition, dielectric etching, metal etching, photoresist removal, and metal deposition through sputtering.

During plasma processes, plasma process-induced damage to devices may occur.

The charged particles generated by plasma may accumulate in a specific region in a device (e.g., a gate region of a transistor), and the resulting high electric field may affect the electrical characteristics of the device. For example, this can lead to shifts in the threshold voltage, reductions in drain current, and degradation of the properties of a gate oxide film.

During a back end of line (BEOL) process, transistor interconnects in a CMOS image sensing device may not fully connected. As a result, charged particles may accumulate in a gate of the transistor, and the accumulated charge may leak into a gate oxide film, leading to reliability degradation and reduced yield of the device.

To protect the transistor gate during the plasma process, a protection device such as a diode or a bipolar junction transistor (BJT) may be implemented inside a CMOS imaging device to mitigate, during the fabrication of the CMOS imaging device, undesired effects caused by unwanted charged particles generated by a plasma process such that the final CMOS imaging devices can exhibit desired operational characteristics as designed without an adverse impact caused by the plasma process.

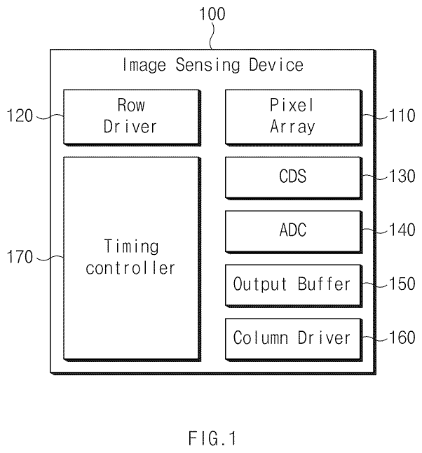

FIG. 1 is a block diagram illustrating an image sensing device 100 based on some implementations of the disclosed technology.

Referring to FIG. 1, the image sensing device 100 may include a pixel array 110, a row driver 120, a correlated double sampler (CDS) 130, an analog-to-digital converter (ADC) 140, an output buffer 150, a column driver 160, and a timing controller 170. The components of the image sensing device 100 illustrated in FIG. 1 are discussed by way of example only, and this patent document encompasses numerous other changes, substitutions, variations, alterations, and modifications.

The pixel array 110 may include a plurality of unit imaging pixels arranged in rows and columns. In one example, the plurality of unit imaging pixels can be arranged in a two dimensional pixel array including rows and columns.

The plurality of unit imaging pixels may convert optical signals into electrical signals, each unit imaging pixel may include a plurality of photoelectric conversion regions, and the photoelectric conversion regions may be commonly connected to at least specific transistors.

The pixel array 110 may include a unit pixel region where unit pixels are disposed and a protection device region disposed adjacent to the unit pixel region.

A plurality of protected devices disposed in the unit pixel region may be electrically connected to the protection devices disposed in the protected device region through a metal line. In some embodiments, the term “metal line” can be used to indicate any type of interconnect.

The protection devices can prevent damage that may occur to the protected devices due to plasma during a semiconductor manufacturing process.

The pixel array 110 may receive driving signals, including a row selection signal, a pixel reset signal and a transfer signal, from the row driver 120. Upon receiving the driving signal, corresponding imaging pixels in the pixel array 110 may be activated to perform the operations corresponding to the row selection signal, the pixel reset signal, and the transfer signal.

The row driver 120 may activate the pixel array 110 to perform certain operations on the imaging pixels in the corresponding row based on commands and control signals provided by controller circuitry such as the timing controller 170.

In some implementations, the row driver 120 may select one or more imaging pixels arranged in one or more rows of the pixel array 110. The row driver 120 may generate a row selection signal to select one or more rows among the plurality of rows.

The row driver 120 may sequentially enable the pixel reset signal for resetting imaging pixels corresponding to at least one selected row, and the transfer signal for the pixels corresponding to the at least one selected row. Thus, a reference signal and an image signal, which are analog signals generated by each of the imaging pixels of the selected row, may be sequentially transferred to the CDS 130.

The reference signal may be an electrical signal that is provided to the CDS 130 when a sensing node of an imaging pixel (e.g., floating diffusion node) is reset, and the image signal may be an electrical signal that is provided to the CDS 130 when photocharges generated by the imaging pixel are accumulated in the sensing node. The reference signal indicating unique reset noise of each pixel and the image signal indicating the intensity of incident light may be generically called a pixel signal as necessary.

CMOS image sensors may use the correlated double sampling (CDS) to remove undesired offset values of pixels known as the fixed pattern noise by sampling a pixel signal twice to remove the difference between these two samples. In one example, the correlated double sampling (CDS) may remove the undesired offset value of pixels by comparing pixel output voltages obtained before and after photocharges generated by incident light are accumulated in the sensing node so that only pixel output voltages based on the incident light can be measured. In some embodiments of the disclosed technology, the CDS 130 may sequentially sample and hold voltage levels of the reference signal and the image signal, which are provided to each of a plurality of column lines from the pixel array 110. That is, the CDS 130 may sample and hold the voltage levels of the reference signal and the image signal which correspond to each of the columns of the pixel array 110.

In some implementations, the CDS 130 may transfer the reference signal and the image signal of each of the columns as a correlate double sampling (CDS) signal to the ADC 140 based on control signals from the timing controller 170.

The ADC 140 is used to convert analog CDS signals into digital signals. In some implementations, the ADC 140 may be implemented as a ramp-compare type ADC. The ramp-compare type ADC may include a comparator circuit for comparing the analog pixel signal with a reference signal such as a ramp signal that ramps up or down, and a timer for performing counting until a voltage of the ramp signal matches the analog pixel signal. In some embodiments of the disclosed technology, the ADC 140 may convert the correlate double sampling (CDS) signal generated by the CDS 130 for each of the columns into a digital signal, and output the digital signal.

The ADC 140 may include a plurality of column counters. Each column of the pixel array 110 is coupled to a column counter, and image data can be generated by converting the correlate double sampling signals received from each column into digital signals using the column counter. In another embodiment of the disclosed technology, the ADC 140 may include a global counter to convert the correlate double sampling signals corresponding to the columns into digital signals using a global code provided from the global counter.

The output buffer 150 may temporarily hold the column-based image data provided from the ADC 140 to output the image data. In one example, the image data provided to the output buffer 150 from the ADC 140 may be temporarily stored in the output buffer 150 based on control signals of the timing controller 170. The output buffer 150 may provide an interface to compensate for data rate differences or transmission rate differences between the image sensing device 100 and other devices.

The column driver 160 may select a column of the output buffer upon receiving a control signal from the timing controller 170, and sequentially output the image data, which are temporarily stored in the selected column of the output buffer 150. In some implementations, upon receiving an address signal from the timing controller 170, the column driver 160 may generate a column selection signal based on the address signal and select a column of the output buffer 150, outputting the image data as an output signal from the selected column of the output buffer 150.

The timing controller 170 may control operations of the row driver 120, the CDS 130, the ADC 140, the output buffer 150 and the column driver 160.

The timing controller 170 may provide at least one of the row driver 120, the CDS 130, the ADC 140, the output buffer 150, and the column driver 160 with a clock signal required for the operations of the respective components of the image sensing device 100, a control signal for timing control, and address signals for selecting a row or column. In an embodiment of the disclosed technology, the timing controller 170 may include a logic control circuit, a phase lock loop (PLL) circuit, a timing control circuit, a communication interface circuit and others.

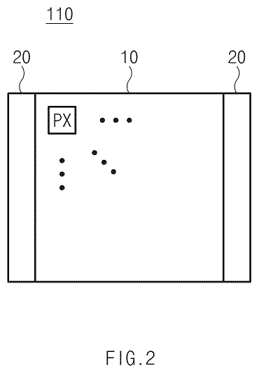

FIG. 2 is a schematic diagram illustrating an example of the pixel array 110 based on an embodiment of the disclosed technology.

Referring to FIG. 2, the pixel array 110 based on an embodiment of the disclosed technology may include a unit pixel region 10 including a plurality of unit pixels (PXs) and a protection device region 20 in contact with the unit pixel region 10.

The unit pixel region 10 and the protection device region 20 may be formed within a semiconductor substrate. The semiconductor substrate may be a silicon substrate doped with impurities.

The plurality of unit pixels (PXs) included in the pixel array 110 may be arranged in a matrix structure. Each unit pixel (PX) may include one or more protection devices and a plurality of protected devices that are electrically coupled to the one or more protection devices such that the plurality of protected devices are under the protection of the one or more protection devices against damage associated with any undesired charged particles induced by the plasma process during the device fabrication.

The protected device may be, for example, a pixel transistor such as a transfer transistor, a drive transistor, or a reset transistor included in each unit pixel (PX).

The protection device region 20 may include a plurality of protection devices electrically connected to the protected devices. The plurality of protection devices may be arranged in a matrix structure within the protection device region 20.

The same type of protection devices may be connected to one protection device with respect to the unit pixels (PXs) arranged in the same row within the unit pixel region 10.

The same type of protected devices may refer to transistors that are included in different unit pixels (PXs) and perform the same function upon receiving the same signal through one signal line.

Although the protection device region 20 shown in FIG. 2 is shown as being disposed on the left and right sides of the unit pixel region 10, the disclosed technology is not limited thereto, and it should be noted that the protection device region 20 may surround the unit pixel region 10 or may be disposed on only one side.

The protected devices included in the unit pixels (PXs) arranged in the same row (ROW) within the unit pixel region 10 may be alternately connected to protection devices arranged in the left protection device region 20 for each row or protection devices arranged in the right protection device region 20 for each row.

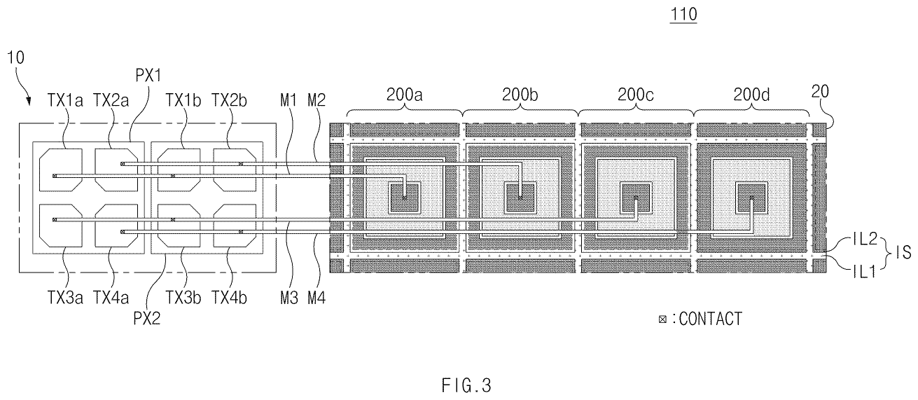

FIG. 3 is a schematic diagram illustrating an example of some parts of the pixel array 110 based on an embodiment of the disclosed technology.

FIG. 3 shows a detailed structure of the unit pixel region 10 and the protection device region 20.

Referring to FIG. 3, a plurality of unit pixels (PX1, PX2) may be arranged in a matrix structure within the unit pixel region 10.

Each of the plurality of unit pixels (PX1, PX2) disposed in the unit pixel region 10 may have a shared pixel structure. In some implementations, the shared pixel structure may include a design where certain components of individual pixels (e.g., transistors or circuitry) are shared between multiple neighboring pixels.

For example, the first unit pixel (PX1) may have a structure in which four photoelectric conversion regions (not shown) share one floating diffusion region (not shown) by first to fourth transfer transistors (TX1a, TX2a, TX3a, TX4a).

Although omitted here for convenience of explanation, each of the unit pixels (PX1, PX2) may further include a drive transistor, a reset transistor, and others.

In some implementations, the protected devices may include the transistors (TX1a, TX2a, TX3a, TX4a, TX1b, TX2b, TX3b, TX4b) included in the unit pixels. In some implementations, protection devices can protect these transistors against plasma-inducted damage.

The pixel array 110 may include a plurality of metal lines (M1, M2, M3, M4) that electrically connect the protected device and the protection device to prevent damage caused by charges accumulated in the gate of the protected device during the plasma process.

The plurality of metal lines (M1, M2, M3, M4) may be interconnection structures (e.g., interconnects) that are separate from a signal line that carries a control signal to the protected device.

The metal lines (M1, M2, M3, M4) may be vertically connected to protected devices (TX1a, TX2a, TX3a, TX4a, TX1b, TX2b, TX3b, TX4b) and protection devices (200a, 200b, 200c) by a contact (CONTACT). The contact (CONTACT) may be, for example, a vertical via. In some implementations, the term “via” can be used to indicate an electrical connection between different layers in a semiconductor device such as an image sensing device.

The protection device region 20 may include a plurality of protection devices (200a, 200b, 200c, 200d) arranged in a matrix structure.

The protection devices (200a, 200b, 200c, 200d) may be connected to the plurality of protected devices (TX1a, TX2a, TX3a, TX4a, TX1b, TX2b, TX3b, TX4b). In some implementations, the protection device 200a may be connected to the protected devices (TX1a, TX2a, TX1b, TX2b), the protection device 200b may be connected to the protected devices (TX2a, TX1b, TX2b), the protection device 200c may be connected to the protected devices (TX3a, TX4a, TX3b, TX4b), and the protection device 200d may be connected to the protected devices (TX4a, TX3b, TX4b).

For example, the first protection device 200a may be connected to the first transfer transistor (TX1a) included in the first unit pixel (PX1) and the first transfer transistor (TX1b) included in the second unit pixel (PX2) through the first metal line (M1).

By connecting a plurality of protected devices to a common protection device, the layout of the pixel array 110 can be efficiently configured.

In the plasma process, the protection devices (200a, 200b, 200c, 200d) may be used to prevent a voltage higher than a reverse breakdown voltage of each of the protection devices (200a, 200b, 200c, 200d) from being applied to gates of the protected transistors (TX1a, TX2a, TX3a, TX4a, TX1b, TX2b, TX3b, TX4b). When a reverse voltage is applied to a diode, almost no current flows up to a certain voltage limit. However, once this limit is exceeded, the current increases sharply. This voltage limit can be referred to as “reverse breakdown voltage.”

In such devices, high-energy ions that are generated in the plasma process during the device fabrication may cause excessive charge to be accumulated in gates of the protected transistors (TX1a, TX2a, TX3a, TX4a, TX1b, TX2b, TX3b, TX4b).

Notably, such charges accumulated in the gates of the protected devices (TX1a, TX2a, TX3a, TX4a, TX1b, TX2b, TX3b, TX4b) can move through an insulation layer located under the gates to cause damage to the insulation layer located under the gates (hereinafter referred to as “gate insulation layer”) as the charges pass through it.

When damage to the gate insulation layer occurs, electrical characteristics (e.g., a threshold voltage, etc.) of the protected devices (TX1a, TX2a, TX3a, TX4a, TX1b, TX2b, TX3b, TX4b) may change, potentially reducing the reliability of the device.

In this example, because the protection devices (200a, 200b, 200c, 200d) are connected to the gates of the protected devices (TX1a, TX2a, TX3a, TX4a, TX1b, TX2b, TX3b, TX4b), charges accumulated in the gates can be prevented from moving to the gate insulation layer.

In various implementations, the protection devices (200a, 200b, 200c, 200d) may be in various specific circuit configurations. In this example, each of the protection devices (200a, 200b, 200c, 200d) may be implemented as a bipolar junction transistor (BJT) including an emitter region, a base region, and a collector region.

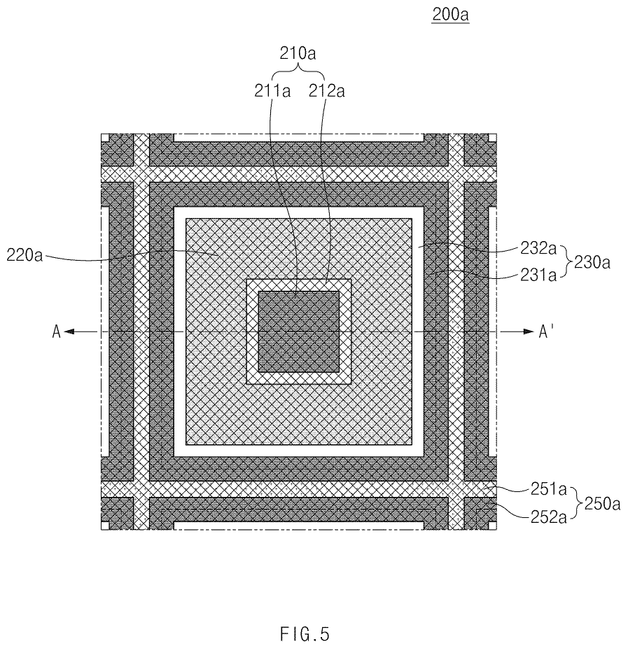

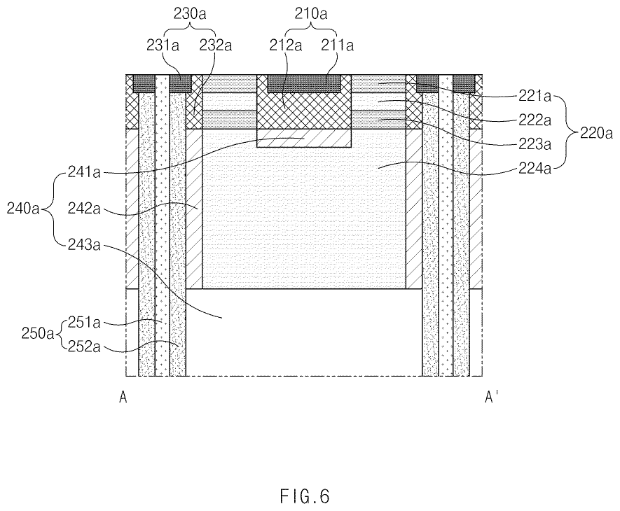

The plurality of regions included in the protection devices (200a, 200b, 200c, 200d) are described in detail below with reference to FIGS. 5 and 6.

The emitter regions included in the protection devices (200a, 200b, 200c, 200d) may be connected to the protected devices through metal lines (M1, M2, M3, M4).

Additionally, the base regions included in the protection devices (200a, 200b, 200c, 200d) may be in a floating state, and the collector regions included in the protection devices (200a, 200b, 200c, 200d) may be grounded to a ground voltage.

Each of the protection devices (200a, 200b, 200c, 200d) may have a PNP-type bipolar junction transistor (BJT) structure. In some implementations, the emitter region included in each of the protection devices (200a, 200b, 200c, 200d) may be a region doped with P-type impurities, the base region included in each of the protection devices (200a, 200b, 200c, 200d) may be a region doped with N-type impurities, and the collector region included in each of the protection devices (200a, 200b, 200c, 200d) may be a region doped with P-type impurities.

Since the protection devices (200a, 200b, 200c, 200d) each having a BJT structure are connected to the protected devices (TX1a, TX1b, TX2a, TX2b, TX3a, TX3b, TX4a, TX4b), a bypass path along which charges can move from the protected devices (TX1a, TX1b, TX2a, TX2b, TX3a, TX3b, TX4a, TX4b) to the protection devices (200a, 200b, 200c, 200d) may be formed during the plasma process. As electric charges move through the bypass path, damage to the gate insulation layer included in the protected devices (TX1a, TX1b, TX2a, TX2b, TX3a, TX3b, TX4a, TX4b) can be prevented.

An isolation structure (IS) may be provided between adjacent protection devices (200a, 200b, 200c, 200d).

The isolation structure (IS) may include a first isolation layer (IL1) and a second isolation layer (IL2). The first isolation layer (IL1) may have a front deep trench isolation (FDTI) structure extending from a front surface of a semiconductor substrate provided in the pixel array 110 to a back surface opposite to the front surface of the semiconductor substrate. The second isolation layer (IL2) may have a layer doped with impurities.

In one embodiment, the first isolation layer (IL1) may include an insulation layer. Based on another embodiment, the first isolation layer (IL1) may further include a polysilicon layer at the center of the insulation layer. In another embodiment, the first isolation layer (IL1) may include only a polysilicon layer.

The isolation structure (IS) may further include a high-concentration P-type impurity layer IL2 (e.g., a second isolation layer) formed along a sidewall of the first isolation layer (IL1).

The second isolation layer (IL2) may be located below the first collector layer included in the collector region (see dotted line IL2 shown in FIG. 3).

The isolation structure (IS) may electrically isolate adjacent protection devices (200a, 200b, 200c, 200d) from each other.

In some implementations, the isolation structure (IS) may electrically isolate the base regions respectively included in the protection devices (200a, 200b, 200c, 200d) from each other.

The first isolation layer (IL1) included in the isolation structure (IS) may include silicon oxide or silicon nitride. The isolation structure (IS) may be formed as a grid structure within the protection device region 20 included in the pixel array 110.

Although FIG. 3 shows that the first isolation layer (IL1) is formed continuously throughout the protection device region 20 for convenience of description, the first isolation layer (IL1) may also be formed discontinuously within the protection device region 20.

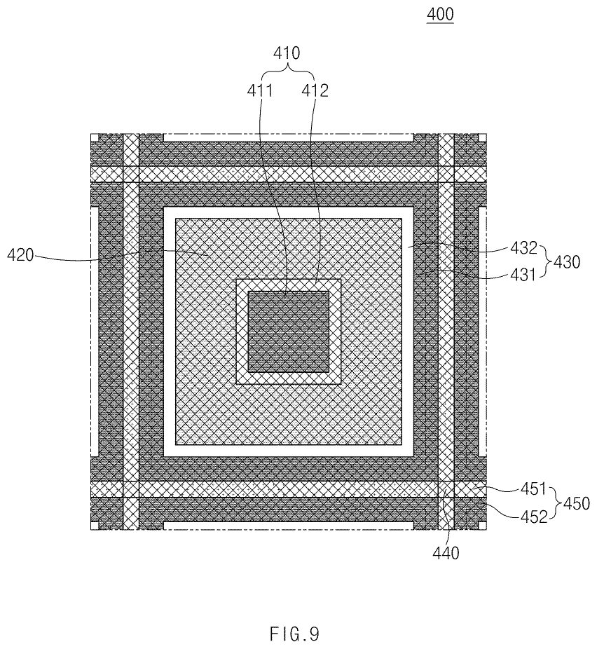

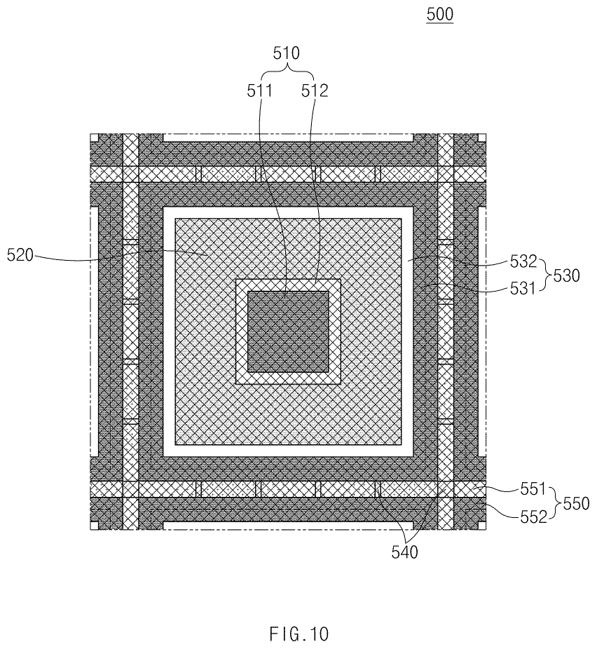

An embodiment in which the first isolation layer (IL1) is formed discontinuously will be described in detail with reference to FIGS. 9 and 10.

In an embodiment, an isolation region (not shown) for isolating the unit pixel region 10 and the protection device region 20 from each other may be additionally provided between the unit pixel region 10 and the protection device region 20.

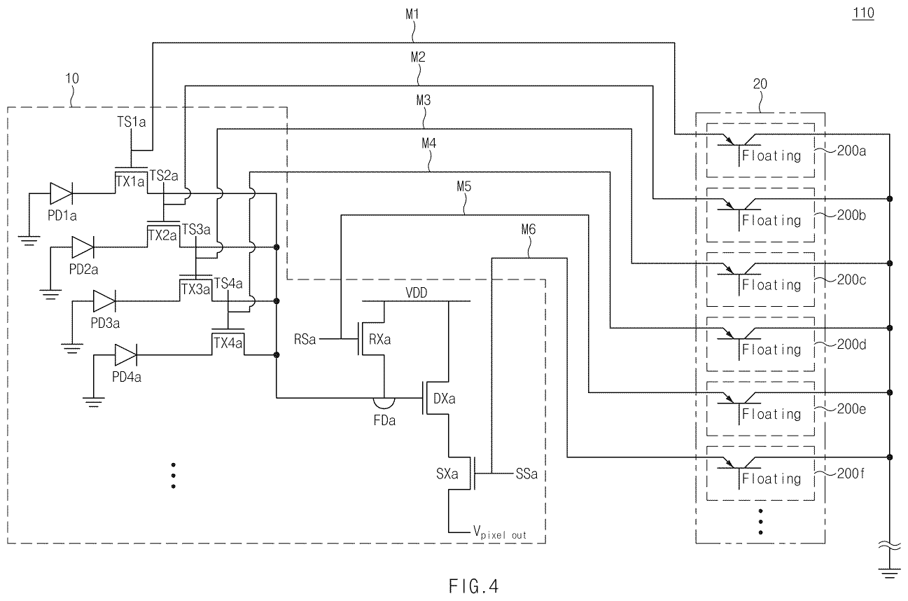

FIG. 4 is a circuit diagram illustrating an example of some parts of an equivalent circuit of the image sensing device based on an embodiment of the disclosed technology.

An equivalent circuit diagram corresponding to the first unit pixel (PX1) of FIG. 3 may be shown in FIG. 4.

For example, the first unit pixel (PX1) may include four photoelectric conversion regions (PD1a, PD2a, PD3a, PD4a), and may have a shared pixel structure in which the photoelectric conversion regions (PD1a, PD2a, PD3a, PD4a) are connected to the floating diffusion region (FDa) through the transfer transistors (TX1a, TX2a, TX3a, TX4a).

However, the above-described structure is merely an example, and the disclosed technology can be implemented in some embodiments to use unit pixels other than two-shared pixels or a shared pixel structure.

The first unit pixel (PX1) may further include a drive transistor (DXa), a selection transistor (SXa), and a reset transistor (RXa).

The transfer transistors (TX1a, TX2a, TX3a, TX4a), the selection transistor (SXa), and the reset transistor (RXa) may be protected devices protected by the protection devices (200a, 200b, 200c, 200d, 200e, 200f).

In some embodiments, the first unit pixel (PX1) may further include transistors (e.g., a gain conversion transistor, a blooming transistor) that are not shown as protected devices.

The photoelectric conversion regions (PD1a, PD2a, PD3a, PD4a) may be photodiodes, each of which is formed in a semiconductor substrate includes a plurality of impurity regions. In another embodiment, each of the photoelectric conversion regions (PD1a, PD2a, PD3a, PD4a) may be implemented as a photodiode, a phototransistor, a photogate, a pinned photodiode (PPD), or a combination thereof.

In the following description, it is assumed that each of the photoelectric conversion regions (PD1a, PD2a, PD3a, PD4a) is implemented as a photodiode as an example.

The photoelectric conversion regions (PD1a, PD2a, PD3a, PD4a) may be formed as N-type doped regions in the semiconductor substrate (SUB) through an ion implantation process that implants N-type ions. The photoelectric conversion regions (PD1a, PD2a, PD3a, PD4a) may include a structure in which a plurality of doped regions is stacked in a vertical direction.

The photoelectric conversion regions (PD1a, PD2a, PD3a, PD4a) may be arranged across as large a region as possible to increase light reception (Rx) efficiency of the unit pixel. The photoelectric conversion regions (PD1a, PD2a, PD3a, PD4a) may individually output signals corresponding to incident light.

The transfer transistors (TX1a, TX2a, TX3a, TX4a) may receive different transfer control signals (TS1a, TS2a, TS3a, TS4a), respectively. The transfer transistors (TX1a, TX2a, TX3a, TX4a) may transmit electrons generated by the photoelectric conversion regions (PD1a, PD2a, PD3a, PD4a) to the floating diffusion region (FDa) in response to voltage levels of the transfer control signals (TS1a, TS2a, TS3a, TS4a).

The floating diffusion region (FDa) may operate as a sensing node of the first unit pixel (PX1). When electrons are transferred from the photoelectric conversion regions (PD1a, PD2a, PD3a, PD4a) to the floating diffusion region (FDa), the voltage level of the floating diffusion region (FDa) may change. The floating diffusion region (FDa) may be connected to the gate of the drive transistor (DXa).

The drive transistor (DXa) connected to the floating diffusion region (FDa) may operate as a source follower transistor that amplifies a voltage change corresponding to electrons stored in the floating diffusion region (FDa).

One end of the drive transistor (DXa) may be connected to a pixel voltage (VDD), and the other end of the drive transistor (DXa) may be connected to the selection transistor (SXa).

The first selection transistor (SXa) may determine whether to output the pixel signal (V_{pixel_out}) corresponding to the voltage change amplified by the drive transistor (DXa). Whether or not the selection transistor (SXa) outputs the pixel signal (V_{pixel_out}) may be determined depending on a voltage level of the selection control signal (SSa) provided to a gate electrode of the selection transistor (SXa). The output pixel signal (V_{pixel_out}) may be processed by the image sensing device 100 to generate a signal corresponding to incident light.

The reset transistor (RXa) may remove electrons from the floating diffusion region (FDa) and the photoelectric conversion regions (PD1a, PD2a, PD3a, PD4a) connected to the floating diffusion region (FDa), and may reset the first unit pixel (PX1) to the pixel voltage (VDD).

Whether to perform a reset operation on the first unit pixel (PX1) may be determined depending on a voltage level of the reset control signal (RSa) provided to the reset transistor (RXa).

The protected devices (TX1a, TX2a, TX3a, TX4a, RXa, SXa) may be connected to the protection devices (200a, 200b, 200c, 200d, 200e, 200f) through the metal lines (M1, M2, M3, M4, M5, M6), respectively. One protection device (e.g., 200a) may be in common contact with the same protected device located in the same row, but is omitted from the drawing.

For example, the first protection device 200a may be in common contact with the first transfer transistor (TX1a) included in the first unit pixel (PX1) and the first transfer transistor (TX1b) included in the second unit pixel (PX2), both of which are located in the same row as the first unit pixel (PX1), through the first metal line (M1).

Each of the first to sixth protection devices (200a, 200b, 200c, 200d, 200e, 200f) may be implemented as a BJT including an emitter, a base, and a collector, respectively.

The metal lines (M1, M2, M3, M4, M5, M6) may connect the gate of the protected device (e.g., TX1a) and the emitter of the protection device (e.g., 200a) to each other.

In addition, the base of the protection device (e.g., 200a) may be in a floating state, and the collector may be grounded.

The first to sixth protection devices (200a, 200b, 200c, 200d, 200e, 200f) may guarantee a sufficient breakdown voltage range with respect to control signals (TS1a, TS2a, TS3a, TS4a, RSa, SSa) applied to the gates of the protected devices (TX1a, TX2a, TX3a, TX4a, RXa, SXa), noise due to leakage current can be prevented.

FIG. 5 is a plan view illustrating an example of the first protection device 200a shown in FIG. 3 based on an embodiment of the disclosed technology.

Referring to FIG. 5, the first protection device 200a may include an emitter region 210a, a base region 220a formed to surround the emitter region 210a, a collector region 230a formed to surround the base region 220a, and an isolation structure 250a disposed between adjacent protection devices.

In FIG. 5, the emitter region 210a may include a first emitter layer 211a doped with P-type impurities and a second emitter layer 212a doped with P-type impurities. The impurity concentration of the first emitter layer 211a may be higher than the impurity concentration of the second emitter layer 212a.

The base region 220a may be a region doped with N-type impurities. The base region 220a shown in FIG. 5 may be at least a partial region of the first base layer included in the base region 220a.

The collector region 230a may include a first collector layer 231a doped with P-type impurities, and a second collector layer 232a doped with P-type impurities while contacting the first collector layer 231a. The impurity concentration of the first collector layer 231a may be the same as that of the first emitter layer 211a, and may be higher than the impurity concentration of the second collector layer 232a.

The isolation structure 250a may be located between adjacent protection devices. The isolation structure 250a may include a first isolation layer 251a located between the collector regions 230a, and a second isolation layer 252a formed to at least partially overlap the collector region 230a.

The first isolation layer 251a may be formed continuously within the protection device region.

As the first isolation layer 251a is continuously formed within the protection device region, the collector regions 230a respectively included in different adjacent protection devices 400 may be electrically isolated from each other.

The second isolation layer 252a may be formed by etching a region for forming the first isolation layer 251a within the substrate region and then performing plasma ion implantation (i.e., plasma doping PLAD) of P-type impurities through the etched region.

The second isolation layer 252a may be a region in which P-type impurities are diffused from the etched region to the substrate region.

FIG. 6 is a cross-sectional view illustrating an example of the first protection device taken along the first cutting line A-A′ shown in FIG. 5 based on an embodiment of the disclosed technology.

FIG. 6 is a cross-sectional view of the protection device 200a disposed in the protection device region 20.

The protection devices (200a, 200b, 200c, 200d, etc.) may have substantially the same structure; therefore redundant descriptions will be omitted here for brevity.

The first protection device 200a may include an emitter region 210a, a base region 220a, a collector region 230a, a substrate region 240a, and an isolation structure 250a.

The emitter region 210a may include a first emitter layer 211a and a second emitter layer 212a. The first emitter layer 211a may be doped with P-type impurities, and the second emitter layer 212a may be formed below the first emitter layer 211 and doped with a lower concentration of P-type impurities than the first emitter layer 211a.

The first emitter layer 211a may be a region connected to the first metal line (M1). In order to reduce resistance between the first emitter layer 211a and the first metal line (M1), the first emitter layer 211a may be doped with a high concentration of P-type impurities. In one embodiment, the first emitter layer 211a may be doped with P-type impurities so that the doped P-type impurities can form a shallow junction.

The second emitter layer 212a may be a region formed earlier than the first emitter layer 211a. In other words, after the second emitter layer 212a is formed in the semiconductor substrate, the first emitter layer 211a may be doped with a higher concentration of impurities than the second emitter layer 212a.

The base region 220a may include a first base layer 221a, a second base layer 222a, a third base layer 223a, and a fourth base layer 224a. The first base layer 221a may be doped with a high concentration of N-type impurities. The second base layer 222a may be formed below the first base layer 221a, and may be doped with a lower concentration of N-type impurities than the first base layer 221a. The third base layer 223a may be doped with a lower concentration of N-type impurities than the second base layer 222a. The fourth base layer 224a may be formed below the third base layer 223a, and may be doped with a lower concentration of N-type impurities than the third base layer 223a.

In other words, the concentration of the base region 220a may gradually decrease from the first base layer 221a to the fourth base layer 224a.

In another embodiment, the base region 220a may further include a plurality of layers each having gradually changing concentration. The first base layer 221a included in the base region 220a may be in a floating state in a manner that electric potential is not fixed.

The collector region 230a may include a first collector layer 231a and a second collector layer 232a. The first collector layer 231a may be doped with a high concentration of P-type impurities and may be formed below the first collector layer 231a. The second collector layer 232a may be doped with a lower concentration of P-type impurities than the first collector layer 231a.

The P-type impurity concentration of the first collector layer 231a may be the same as the P-type impurity concentration of the first emitter layer 211a.

The first collector layer 231a may be a region to which a ground voltage is connected. As the first collector layer 231a is connected to the ground voltage, carriers inside the first protection device 200a may be captured through the collector region 230a.

The substrate region 240a may include a first substrate layer 241a, a second substrate layer 242a, and a third substrate layer 243a. The first substrate layer 241a may be disposed between the emitter region 210a and the base region 220a. The second substrate layer 242a may be disposed between the base region 220a and the isolation structure 250a. The third substrate layer 243a may be located below the base region 220a.

In one embodiment, each of the first substrate layer 241a and the second substrate layer 242a may be a silicon substrate region doped with P-type impurities. Each of the first substrate layer 241a and the second substrate layer 242a may be a region doped with a lower concentration of P-type impurities than the second collector layer 232a. In addition, each of the first substrate layer 241a and the second substrate layer 242a may be a region doped with a lower concentration of P-type impurities than the third substrate layer 243a.

In another embodiment, each of the first substrate layer 241a and the second substrate layer 242a may be a silicon substrate region not doped with impurities.

The third substrate layer 243a may be a region doped with P-type impurities having a concentration that is equal to or higher than that of the second collector layer 232a and lower than that of the first collector layer 231a.

The isolation structure 250a may include a first isolation layer 251a and a second isolation layer 252a. The first isolation layer 251a may extend from one surface of the semiconductor substrate to the other surface of the semiconductor substrate. The second isolation layer 252a may be formed along a sidewall of the first isolation layer 251a, and may extend from a bottom surface of the first collector layer 231a to the other surface of the semiconductor substrate.

The second isolation layer 252a may be a region doped with a lower concentration of P-type impurities than the first collector layer 231a or the first emitter layer 211a. The P-type impurity concentration of the second isolation layer 252a may be higher than the P-type impurity concentration of the second collector layer 232a and the third substrate layer 243a.

In addition, the P-type impurity concentration of the second isolation layer 252a may be the same as the P-type impurity concentration of the second emitter layer 212a.

The first isolation layer 251a may be formed through patterning, etching, and deposition processes. In some implementations, a region in which the first isolation layer 251a will be formed is first patterned, a region in which the first isolation layer 251a will be formed is etched through the etching process, and then a first isolation layer 251a including a polysilicon layer or a silicon oxide may be formed through the deposition process.

The second isolation layer 252a may be formed by etching the region to be used for formation of the first isolation layer 251a before depositing the first isolation layer 251a including a silicon layer, silicon oxide, etc., and then performing plasma ion implantation (i.e., plasma doping PLAD) of P-type impurities through the etched region.

As the first isolation layer 251a is formed, the collector region (e.g., 220a) included in the protection device (e.g., 200a) may be physically isolated from the collector region of another protection device. Additionally, since the second isolation layer 252a is formed, adjacent collector regions can be electrically isolated from each other.

The first protection device 200a may include the second isolation layer 252a and the third substrate layer 243a, each of which is doped with P-type impurities, so that the first protection device 200a may have a structure in which the collector region is substantially expanded.

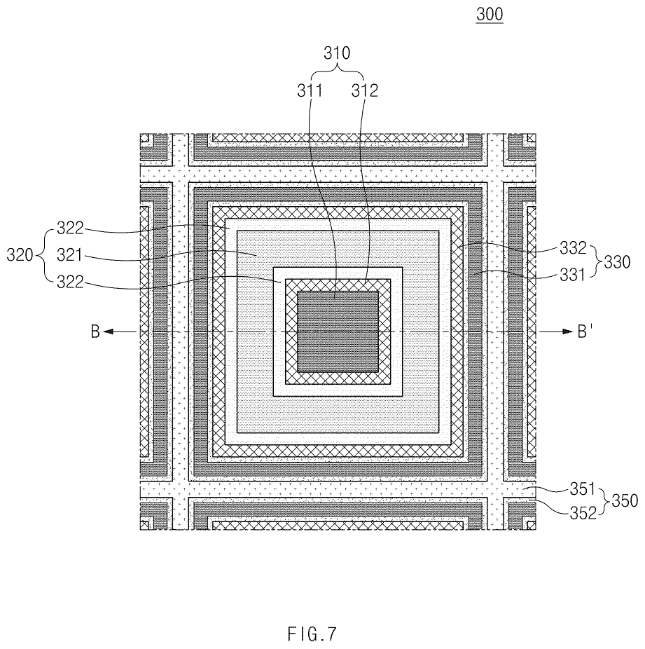

FIG. 7 is a plan view illustrating an example of a protection device based on another embodiment of the disclosed technology.

The planar shape of the protection device 300 shown in FIG. 7 is substantially the same as the planar shape of the first protection device 200a described in FIG. 5 except for the presence or absence of STI; therefore redundant descriptions will be omitted here for brevity. The protection device shown in FIG. 7 will hereinafter be described with a focus on the characteristics that are different from those of the first protection device 200a shown in FIG. 5.

In FIG. 7, lower regions (e.g., 312, 322) that are revealed as the STI is formed are shown.

The protection device 300 may include an emitter region (310), a base region 320 formed to surround the emitter region 310, a collector region 330 formed to surround the base region 320, and an isolation structure 350 located between adjacent protection devices.

In FIG. 7, a high-concentration P-type impurity layer (i.e., a second isolation layer) included in the isolation structure may be formed under the first collector layer 331. The second isolation layer 352 located at both sides of the first collector layer 331 may be exposed by the STI structure. A first isolation layer 351 included in the isolation structure may be disposed between the second isolation layers 352.

In the embodiment of FIG. 7, the second emitter layer 312, the second base layer 322, and the second collector layer 332 may be exposed on a plane perpendicular to one surface of the substrate.

In the embodiment of FIG. 7, shallow trench isolation (STI) may be formed not only between the emitter region 310 and the base region 320, but also between the base region 320 and the collector region 330. Further, shallow trench isolation (STI) may be formed between the first collector layers 331 located above the second isolation layer 352.

As the shallow trench isolation (STI) is formed, the second emitter layer 312, the second base layer 322, and the second collector layer 332 may be exposed, and the second isolation layer 352 may then be exposed. Here, the STI may be filled with an insulation material (e.g., silicon oxide or silicon nitride, etc.).

In an embodiment, before the STI is filled with an insulation material, the STI may be formed first, and the first isolation layer 351 may be formed within the formed STI. Subsequently, as the STI is formed, the second isolation layer 352 may be exposed to both sides of the first collector layer 331.

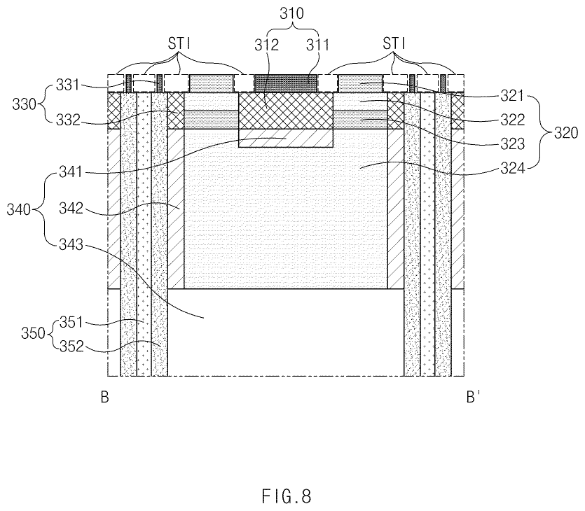

FIG. 8 is a cross-sectional view illustrating an example of the protection device taken along the second cutting line B-B′ shown in FIG. 7 based on another embodiment of the disclosed technology.

The planar shape of the protection device 300 shown in FIG. 8 is substantially the same as the planar shape of the first protection device 200a described in FIG. 6 except for the presence or absence of STI, as such redundant description thereof will herein be omitted for brevity, and the protection device shown in FIG. 8 will hereinafter be described with a focus on the characteristics that are different from those of the first protection device 200a shown in FIG. 6.

The STI may isolate the first emitter layer 311 and the first base layer 321 from each other. The STI may isolate the first base layer 321 and the first collector layer 331 from each other. In addition, the STI may be located above the first isolation layer 351.

In the embodiment, the first isolation layer 351 may be formed after formation of the STI.

The depth of the STI may vary depending on characteristics required for the protection device 300.

The first emitter layer 311, the first base layer 321, and the first collector layer 331, each of which is doped with a high concentration of impurities, may be isolated from each other by the STI, thereby preventing a decrease in the breakdown voltage of the protection device due to junction between high-concentration doped regions.

In addition, as the STI is formed, a punch-through phenomenon between the first emitter layer 311 and the second base layer 322 can be prevented.

When a voltage is provided through the first emitter layer 311, a space charge region located under the first emitter layer 311 is enlarged, thereby having an effect on the second base layer 322.

In some implementations, when an excessive voltage is provided to the protected device and the space charge region of the first emitter layer 311 is enlarged to a critical point or more, the BJT (or diode) function of the protected device 300 is weakened, so that a punch-through phenomenon in which a leakage current is generated may occur.

Therefore, as a separation distance between the first emitter layer 311 and the second base layer 322 is secured through the STI, the punch-through phenomenon can be prevented and the electrical characteristics of the protection device 300 can be improved.

FIG. 9 is a plan view illustrating an example of a protection device 400 based on another embodiment of the disclosed technology.

Referring to FIG. 9, the protection device 400 may include an emitter region 410, a base region 420 surrounding the emitter region 410, a collector region 430 surrounding the base region 420, and an isolation structure 450 located between adjacent protection devices.

Additionally, the protection device 400 may further include a substrate region 440 located between the first isolation layers 451 included in the isolation structure 450.

In FIG. 9, the emitter region 410 may include a first emitter layer 411 and a second emitter layer 412. The first emitter layer 411 may be doped with P-type impurities, and the second emitter layer 412 may be doped with P-type impurities. The impurity concentration of the first emitter layer 411 may be higher than the impurity concentration of the second emitter layer 412.

The base region 420 may be a region doped with N-type impurities.

The collector region 430 may include a first collector layer 431 and a second collector layer 432. The first collector layer 431 may be doped with P-type impurities. The second collector layer 432 may be doped with P-type impurities while contacting the first collector layer 431. The impurity concentration of the first collector layer 431 may be the same as that of the first emitter layer 411, and may be higher than the impurity concentration of the second collector layer 432.

The isolation structure 450 may be located between adjacent protection devices. The isolation structure 450 may include a first isolation layer 451 located between the collector regions 430, and a second isolation layer 452 formed to at least partially overlap the collector region 430.

The first isolation layer 451 may be formed discontinuously within the protection device region.

The first isolation layer 451 may be formed by etching at least a portion of the substrate region 440 and depositing an insulation material or polysilicon in the etched region.

The second isolation layer 452 may be formed by plasma ion implantation (plasma doping PLAD) of P-type impurities through an etched region formed in the substrate region 440. Therefore, even if the etched region is discontinuously formed, the second isolation layer 452 may be formed continuously through impurity diffusion.

In the embodiment of FIG. 9, the first isolation layers 451 may be isolated from other adjacent first isolation layers 451 at a vertex region of the protection device 400. The region between the first isolation layers 451 may be a substrate region 440 as described above. The length of the first isolation layer 451 may be equal to the length of the side of the base region 420.

When the first isolation layer 451 is formed discontinuously, the second isolation layers 452 and the collector regions 430 included in different protection devices 400 may be electrically connected to each other through the substrate region 440 in which the first isolation layer 451 is not formed.

When the second isolation layers 452 and the collector regions 430 included in the different protection devices 400 are electrically connected to each other, the collector region 430 included in the protection devices 400 can be substantially enlarged.

When the collector region 430 is enlarged, the amount of charges required to charge the gate of the protected device that can be removed by the protection device 400 may increase.

FIG. 10 is a plan view illustrating an example of a protection device 500 based on another embodiment of the disclosed technology.

Referring to FIG. 10, the emitter region 510 may include a first emitter layer 511 doped with P-type impurities and a second emitter layer 512 doped with P-type impurities. The impurity concentration of the first emitter layer 511 may be higher than the impurity concentration of the second emitter layer 512.

The base region 520 may be a region doped with N-type impurities.

The collector region 530 may include a first collector layer 531 and a second collector layer 532. The first collector layer 531 may be doped with P-type impurities. The second collector layer 532 may be doped with P-type impurities while contacting the first collector layer 531. The impurity concentration of the first collector layer 531 may be the same as that of the first emitter layer 511, and may be higher than the impurity concentration of the second collector layer 532.

The isolation structure 550 may be located between adjacent protection devices. The isolation structure 550 may include a first isolation layer 551 disposed between the collector regions 530 and a second isolation layer 552 formed to at least partially overlap the collector region 530.

The first isolation layer 551 may be formed discontinuously within the protection device region.

The first isolation layer 551 may be formed by etching at least a portion of the substrate region 540 and depositing an insulation material or polysilicon in the etched region.

A second isolation layer 552 may be formed by plasma ion implantation (plasma doping PLAD) of P-type impurities through an etched region formed in the substrate region 540. Therefore, even if the etched region is discontinuously formed, the second isolation layer 552 may be formed continuously through impurity diffusion.

In the embodiment of FIG. 10, each of the first isolation layers 551 may have a preset length, and the preset length may be shorter than the length of the side of the base region 520.

When the first isolation layer 551 is formed discontinuously, the second isolation layers 552 and the collector regions 530 included in different protection devices 500 may be electrically connected to each other through the substrate region 540 in which the first isolation layer 551 is not formed.

When the second isolation layers 552 and the collector regions 530 included in the different protection devices 500 are electrically connected to each other, the collector region 530 included in the protection devices 500 can be substantially enlarged.

When the collector region 530 is enlarged, the amount of charges required to charge the gate of the protected device that can be removed by the protection device 500 may increase.

As is apparent from the above description, the image sensing device based on some implementations of the disclosed technology can effectively protect a protected transistor against plasma-induced damage during a plasma process while preventing electrical short-circuit between adjacent protection devices.

The embodiments of the disclosed technology may provide a variety of effects capable of being directly or indirectly recognized through the above-mentioned patent document.

Although a number of illustrative embodiments have been described, it should be understood that modifications and enhancements to the disclosed embodiments and other embodiments can be devised based on what is described and/or illustrated in this patent document.

What is claimed is:

1. An image sensing device comprising:
a unit pixel configured to capture incident light for image sensing and include one or more protected devices to be protected against electrical damage; and
a protection device electrically connected to the one or more protected devices and configured to protect the protected device during a plasma process,
wherein the protection device includes:
an emitter region configured to include impurities of a first conductivity type;
a base region configured to surround the emitter region and including impurities of a second conductivity type;
a collector region configured to surround the base region and including impurities of the first conductivity type; and
an isolation structure disposed between the protection device and another protection device adjacent to the protection device and configured to electrically isolate the base region of the protection device from a base region of the other protection device.

2. The image sensing device according to claim 1, wherein:
the first conductivity type is P-type; and
the second conductivity type is N-type.

3. The image sensing device according to claim 1, wherein the isolation structure includes:
a first isolation layer configured to include an insulation material; and
a second isolation layer configured to contact a sidewall of the first isolation layer and including impurities of the first conductivity type.

4. The image sensing device according to claim 1, wherein the emitter region includes:
a first emitter layer configured to include impurities of the first conductivity type; and
a second emitter layer disposed below the first emitter layer and configured to include a lower concentration of impurities of the first conductivity type than the first emitter layer.

5. The image sensing device according to claim 4, wherein the base region includes:
a first base layer configured to include impurities of the second conductivity type;
a second base layer disposed below the first base layer and configured to include a lower concentration of impurities of the second conductivity type than the first base layer;
a third base layer disposed below the second base layer and configured to include a lower concentration of impurities of the second conductivity type than the second base layer; and
a fourth base layer disposed below the third base layer and configured to include a lower concentration of impurities of the second conductivity type than the third base layer.

6. The image sensing device according to claim 5, wherein the collector region includes:
a first collector layer configured to include impurities of the first conductivity type; and
a second collector layer disposed below the first collector layer and configured to include a lower concentration of impurities of the first conductivity type than the first collector layer.

7. The image sensing device according to claim 6, wherein the first emitter layer includes:
impurities of the first conductivity type at the same concentration as the first collector layer.

8. The image sensing device according to claim 6, further comprising:
a shallow trench isolation (STI) structure disposed between the first emitter layer and the first base layer, and disposed between the first base layer and the first collector layer.

9. The image sensing device according to claim 1, wherein:
a gate of the protected device is connected to the emitter region through an interconnect.

10. The image sensing device according to claim 1, wherein:
the protected device includes at least one of a transfer transistor, a selection transistor, or a reset transistor.

11. The image sensing device according to claim 1, wherein:
the base region is in a floating state.

12. The image sensing device according to claim 1, wherein:
the collector region is grounded to a ground voltage.

13. The image sensing device according to claim 3, wherein:
the first isolation layer is continuously formed between the protection device and the other protection device; and
the base region of the protection device is electrically isolated from the base region of the other protection device.

14. The image sensing device according to claim 3, wherein:
the first isolation layer is discontinuously formed between the protection device and the other protection device to include first isolation layer segments separated from each other; and
the base region is electrically connected to the base region of the other protection device.

15. An image sensing device comprising:
a protected device disposed in a unit pixel region; and
a protection device disposed in a protection device region formed to be in contact with the unit pixel region and connected to a circuit or a circuit component of the unit pixel region as a protected device to provide protection to the protected device during a plasma process during fabrication of the image sensing device,
wherein the protection device includes:
an emitter region configured to include P-type impurities;
a base region configured to surround the emitter region and including N-type impurities;
a collector region configured to surround the base region and including the P-type impurities; and
an isolation structure disposed between a base region of the protection device and a base region of another protection device.

16. The image sensing device according to claim 15, wherein the protected device includes:
a gate; and
a gate insulation layer disposed below the gate,
wherein the gate is connected to the emitter region through an interconnect.

17. The image sensing device according to claim 15, wherein:
the protected device includes at least one of a transfer transistor, a selection transistor, or a reset transistor.

18. The image sensing device according to claim 15, further comprising:
a shallow trench isolation (STI) structure disposed between the emitter region and the base region, and disposed between the base region and the collector region.

19. The image sensing device according to claim 15, wherein the isolation structure includes:
a first isolation layer configured to include an insulation material; and
a second isolation layer configured to contact a sidewall of the first isolation layer and including the P-type impurities.

20. The image sensing device according to claim 19, wherein:
the second isolation layer is formed by performing plasma ion implantation.
